(19) United States
(12) Patent Application Publication
(10) Pub. No.: US 2010/0014208 A1
(43) Pub. Date: Jan. 21, 2010

(54) SUBSTRATE HOLDER

(75) Inventors: Yoshida Tatsuhiko, Kawasaki-shi (JP); Kaneko Kazuaki, Kawasaki-shi (JP); Tanaka Yoh, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANLEVA CORPORATION, Kawasaki-shi (JP)

(21) Appl. No.: 12/495,205

(22) Filed: Jun. 30, 2009

(30) Foreign Application Priority Data
Jul. 10, 2008 (JP) 2008-179792
Jul. 10, 2008 (JP) 2008-179793

(51) Int. Cl. H01L 21/683; C23C 16/458; H01L 21/465

(52) U.S. Cl. 361/234; 118/723 R; 156/345.52; 257/E21.485

(57) ABSTRACT

A substrate holder which has an electrostatic chuck on a substrate holding side of a holder main body and electrostatically adsorbs a substrate includes: a heating unit which is built in the electrostatic chuck and heats the substrate; a circulation medium distribution path which is formed inside the holder main body and connected to a circulation medium supplying unit which circulates and supplies a circulation medium; a heat transference varying unit which is formed by sealing a heat transfer gas in a gap between the holder main body and the electrostatic chuck and connected to a heat transfer gas supply system which can control a sealing pressure; and a gas sealing unit which is formed by sealing a heat transfer gas in a gap between the electrostatic chuck and the substrate and connected to the heating transfer gas supply system.

### BACKGROUND OF THE INVENTION

1. Field of the Invention

The present invention relates to a semiconductor holder which holds a substrate in a vacuum vessel of a plasma processing apparatus by electrostatic adsorption to make it possible to control a substrate temperature.

2. Description of the Related Art

A substrate holder (substrate supporting apparatus) which holds a substrate (wafer) is arranged in a vacuum vessel of a plasma processing apparatus such as a sputtering apparatus or an etching apparatus, and a substrate temperature is generally controlled.

For example, a substrate supporting apparatus including a base member which has a heater or a cooler built therein and an electrostatic chuck which adsorptively holds a wafer on an upper portion of the base member through a heat transfer sheet is proposed (see Japanese Patent Application Laid-Open No. 2001-110883). In the base member, a gas feeding path which feeds a heat transfer gas is formed, and a gas accumulating trench which communicates with the gas feeding path and accumulates the heat transfer gas is formed on an upper surface of the gas feeding path. When the heat transfer gas is supplied to the gas accumulating trench, thermal coupling caused by the heat transfer gas occurs in a non-contact portion between the base member and the electrostatic chuck (see Japanese Patent Application Laid-Open No. 2001-110883).

Furthermore, a wafer processing apparatus which includes a substrate holder having a heat function and an electrostatic chuck function and transmits a heat input to a wafer on the substrate holder to a water-cooling jacket through a heat conductive member having elasticity is proposed (see Japanese Patent Application Laid-Open Nos. 2004-088063 and 2004-087869).

Furthermore, an etching apparatus including a heating mechanism and a cooling mechanism which are formed on a substrate holder is proposed (see Japanese Patent Application Laid-Open No. 10-303185). In this etching apparatus, the substrate holder is heated in advance to set a substrate temperature at a process temperature before the start of etching, and an operation is stopped at or after the start of etching to switch the operation to heating by a plasma. A thermal balance temperature is controlled to a process temperature by both the heating and cooling by the plasma.

A plasma processing apparatus in which a heater is built in a placing table capable of generating electrostatic adsorption and which can apply a high-frequency voltage in a state in which a lower cooling jacket and a heat transfer sheet member are pressed on a lower surface of the placing table is proposed (see Japanese Patent Application Laid-Open No. 2000-299288).

### BRIEF SUMMARY OF THE INVENTION

In the technique in Japanese Patent Application Laid-Open No. 2001-110883, the base member and the electrostatic chuck communicate with each other, the electrostatic chuck and the wafer communicate with each other, and heat transfer gases fed from a common supply source (supply system) are fed. Therefore, the heat transfer gases cannot be independently controlled, and a wafer temperature is uniquely determined on the basis of a temperature control condition. For example, when the wafer temperature is to be controlled at a high temperature ranging from 200 to 500° C., due to a change in heat input energy by a plasma and heating or waste heat emission by the heater or the cooler of the base member, overall energy cannot be easily controlled, making the wafer temperature unstable. Therefore, when the apparatus is used in the above temperature range, a heat transfer gas is not used.

Furthermore, with respect to the gas accumulating trenches formed between the base member and the electrostatic chuck and between the electrostatic chuck and the wafer, a pressure of a cooling gas is merely regulated to 1 to 30 Torr. Therefore, in response to a change in plasma heat input energy caused by a change of process conditions, a heat transfer coefficient cannot be easily controlled by adjusting the pressure of the heat transfer gas. The wafer temperature is thus deteriorated in controllability.

In a technique in Japanese Patent Application Laid-Open No. 2004-088063, in order to control the wafer temperature to a set temperature, as a heat conductive member arranged between the substrate holder and the cooling jacket, a member having a thermal conductance of 0.3 to 1 W/K is used. For example, Japanese Patent Application Laid-Open No. 2004-088063 discloses that, when a cooling jacket temperature and a temperature of the substrate holder are 50° C. and 200 to 500° C., respectively, an amount of heat input ranging from 307 W to 1168 W can be controlled. According to the control method, although the amount of heat input can be controlled in a stationary state, in an environment in which a heat input generated by a plasma or the like is transitionally generated, a thermal conductance of the heat transfer member is as small as 0.3 to 1 W/K. For this reason, the temperature of the substrate temporarily increases to a temperature almost twice the set temperature. Furthermore, 10 seconds or more are required until the temperature is stationarily controlled to the set temperature.

In the temperature control method, the substrate temperature varies in the process processing step, and desired process performance cannot be disadvantageously obtained. This temperature controllability is regulated by thermal conductance of the substrate holder and the cooling jacket, i.e., a capability of emitting a waste heat input to the substrate holder through the cooling jacket. Therefore, since the thermal conductance of 0.3 to 1 W/K of the heat transfer member limits a waste heat emitting capability, control response of the set temperature is good when the heat input is stationary. However, in the environment in which the heat input is transitional, the control response is poor because the thermal conductance is small. In a transition state of the heat input at the start of process processing, the substrate temperature varies.

Therefore, in any one of a state in which heat input from a plasma or the like does not occur, a state in which a heat input from a plasma or the like transitionally occurs, and a state in which a heat input stationarily occurs, in order to control a substrate temperature to the set temperature ±10° C. within 10 seconds and use a circulation water of a water-cooling jacket at a temperature of 100° C. or less, the apparatus must have a function of making a thermal conductance between the substrate holder and the water-cooling jacket variable.

A technique in Japanese Patent Application Laid-Open No. 2004-087869 is used at a process temperature of 200° C. or less, and does not suppose control of the substrate temperature under a temperature condition of 200 to 500° C. In contrast, in techniques in Japanese Patent Application Laid-Open Nos. 10-303185 and 2000-299288, a substrate holder which is controlled to a set temperature ranging form 200 to 500° C. and which has a mechanism capable of performing heat exchange through a circulation medium for heat exchange is used. The substrate holder of this type is easily contaminated by leakage, adhesion, and the like of the circulation medium at the time of maintenance because the circulation medium is oil-based. The substrate holder is inconveniently handled in a clean room. The cooling medium (circulation medium) frequently has combustibility, and is used with a safety risk in a clean room.

The present invention has been made in consideration of the above circumstances, and an object of the invention is to provide a substrate holder which can accurately control a substrate temperature at a high speed within a temperature range of 200 to 500° C. while giving a waste heat emitting function for a heat input by a plasma or the like to a non-combustible cooling medium.

A configuration of the present invention to achieve the above object is as follows.

More specifically, according to one aspect of the present invention, there is provided a substrate holder which has an electrostatic chuck on a substrate holding side of a holder main body and electrostatically adsorbs a substrate, including: a heating unit which is built in the electrostatic chuck and heats the substrate; a circulation medium distribution path which is formed inside the holder main body and connected to a circulation medium supplying unit which circulates and supplies a circulation medium; a heat transference varying unit which is formed by sealing a heat transfer gas in a gap between the holder main body and the electrostatic chuck and connected to a heat transfer gas supply system which can control a sealing pressure; and a gas sealing unit which is formed by sealing a heat transfer gas in a gap between the electrostatic chuck and the substrate and connected to the heating transfer gas supply system.

According to another aspect of the present invention, there is provided a semiconductor holder which has an electrostatic chuck on a substrate holding side of a holder main body and electrostatically adsorbs a substrate, including: a heating unit which is built in the electrostatic chuck and heats the substrate; a circulation medium distribution path which is formed inside the holder main body and connected to a circulation medium supplying unit which circulates and supplies a circulation medium; a heat transference varying unit which is partitioned and formed as a sealed space for a heat transfer gas above the circulation medium distribution path inside the holder main body and which is connected to a heat transfer gas supply system which can adjust a sealing pressure.

According to the present invention, the substrate holder includes the heat transference varying unit which adjusts a pressure of the heat transfer gas to make it possible to control a heat transfer coefficient. Therefore, a substrate temperature can be accurately controlled at a high speed within a temperature range of 200 to 500° C.

Since the heat transference varying unit can vary a heat transference obtained by gas sealing, the cooling medium can be used at a temperature of about 200° C. or less. Therefore, a waste heat emitting function for a heat input caused by a plasma or the like can also be given to the cooling medium which is free from combustibility.

### BRIEF DESCRIPTION OF THE SEVERAL VIEWS OF THE DRAWINGS

FIG. 1 is a schematic diagram showing a first embodiment of a substrate holder according to the present invention;

FIG. 2 is a diagram for explaining a change in temperature of the substrate holder according to the present invention in relation to a conventional change in temperature;

FIG. 3 is a schematic diagram showing a substrate holder according to a second embodiment;

FIG. 4 is a sectional view showing a transverse sectional structure of a heat transference varying unit in the second embodiment;

FIG. 5 is a schematic diagram showing a third embodiment of the semiconductor holder according to the present invention; and

FIG. 6 is a schematic diagram showing a substrate holder according to a fourth embodiment.

### DETAILED DESCRIPTION OF THE INVENTION

Embodiments of the present invention will be described below with reference to the accompanying drawings. However, the present invention is not limited to the embodiments.

### First Embodiment

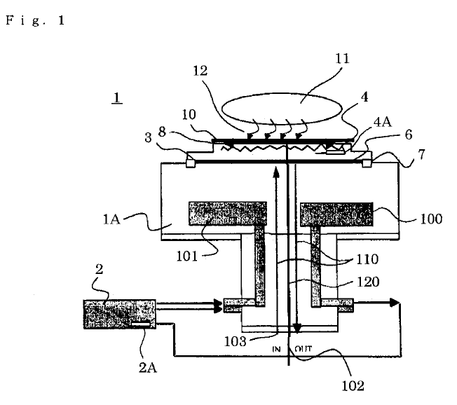

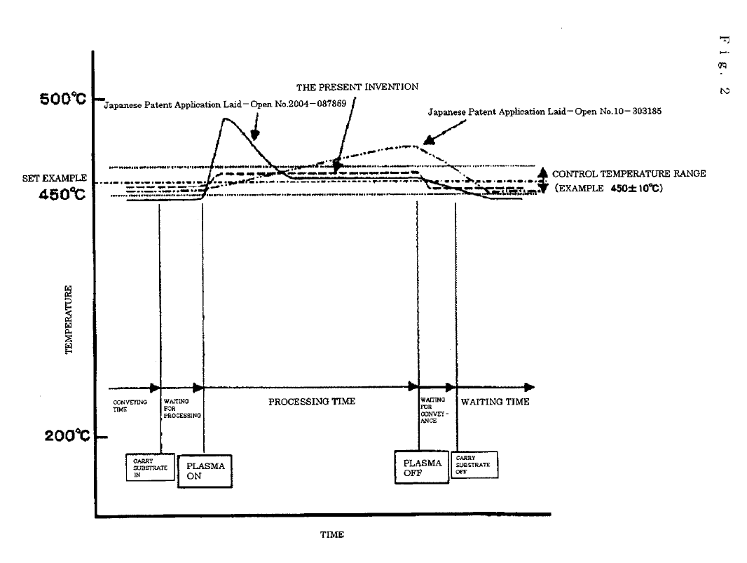

FIG. 1 is a schematic diagram showing a first embodiment of a substrate holder according to the present invention. FIG. 2 is a diagram for explaining a change in temperature of the substrate holder according to the present invention in relation to a conventional change in temperature.

As shown in FIG. 1, a substrate holder 1 according to the first embodiment is arranged in a vacuum vessel (not shown) of a plasma processing apparatus typified by a sputtering apparatus. The substrate holder 1 holds a substrate 10 on an electrostatic chuck 3 arranged on a substrate holding side (upper portion) of a holder main body 1A by electrostatic adsorption.

The holder main body 1A is, for example, a disk-like or columnar support member which supports a semiconductor wafer serving as the substrate 10. A circulation medium distribution path 100 to cause a circulation medium (cooling medium) 101 to flow is partitioned and formed inside the holder main body 1A. A circulation medium supplying unit 2 to circulate and supply the circulation medium 101 is connected to the circulation medium distribution path 100. The circulation medium 101 is circulated into the circulation medium distribution path 100 to give a heat exchange function and a waste heat emitting function to the holder main body 1A. In the embodiment, a circulation chiller with a temperature control sensor 2A is employed as the circulation medium supplying unit 2, and the circulation chiller 2 can be controlled to a temperature of about 200° C. or less (more specifically, temperature of 100 to 250° C.). As the circulation medium 101, for example, a fluorine medium, cooling water mixed with ethylene-glycol, or pure water can be used.

The electrostatic chuck 3 incorporates therein an electrostatic adsorption electrode and holds the substrate 10 by electrostatic adsorption. In the electrostatic chuck 3, a heating unit 4 to heat the substrate 10 is incorporated. In the embodiment, as the heating unit 4, for example, a heater with a temperature control sensor 4A the temperature of which can be raised to 200 to 500° C. is employed.

A heat transfer gas (sealed gas) 103 is sealed in a gap between the holder main body 1A and the electrostatic chuck 3, and a heat transference varying unit 6 connected to a heat transfer gas supply system 110 the sealing pressure of which can be adjusted is formed. A ring-like heat-insulating member 7 is arranged aground the heat transference varying unit 6 partitioned in the gap between the holder main body 1A and the electrostatic chuck 3. As the heat-insulating member 7, for example, a material such as alumina or stainless steel having a heat transfer coefficient of 25 W/m²·K or less is given. However, the heat-insulating member 7 is more preferably formed of a material such as zirconia or quartz having a heat transfer coefficient of less than 10 W/m²·K. The heat-insulating member 7 thermally insulates the holder main body 1A from the electrostatic chuck 3 to make it possible to control a heat transfer coefficient by adjusting a gas sealing pressure.

The heat transference varying unit 6 sets a gap size at which 1 or more of a Knudsen number (Ku=λ/L where λ (m): a mean free path of molecules and L (m): typical length) is obtained on the basis of a mean free path of a gas to be used such that the heat transfer coefficient is made variable by adjusting the sealing pressure of the heat transfer gas. The Knudsen number is set to a value which is sufficiently larger than 1 because inter-molecule collision at this time can be neglected and a fluid can be handled as a continuum.

As the heat transfer gas, for example, an inert gas such as argon (Ar), helium (He), or nitrogen (N₂) can be used. When Ar and He are used at a substrate set temperature of 450° C., a width of a gap between the holder main body 1A and the electrostatic chuck 3 is set to 0.15 to 0.5 mm, and the sealing pressure is set to 100 Pa and 1000 Pa. At this time, a heat transfer coefficient becomes variable as described in the following Table 1. As in a case where there is no heat input 12 by plasma 11 or the like, when a waste heat emitting energy from the circulation medium 101 of the holder main body 1A is desired to be reduced, the sealing pressure is set to 0 Pa to minimize the heat transfer coefficient.

TABLE 1

| | | | | |
|---|---|---|---|---|
| Ar gas | 100 | Pa | 1000 | Pa |
| Gas sealed Gap 0.15 mm | 10 | W/m² · K | 100 | W/m² · K |
| He gas | 100 | Pa | 1000 | Pa |
| Gas sealed Gap 0.5 mm | 240 | W/m² · K | 2400 | W/m² · K |

A heat transfer gas (substrate rear-surface gas) 102 is also sealed in a gap between the electrostatic chuck 3 and the substrate 10, and a gas sealing unit 8 connected to a heat transfer gas supply system 120 is formed therein. The gas sealing unit 8 seals the rear surface of the substrate 10 with a gas, and performs heat transfer between the substrate 10 and the electrostatic chuck 3. As the heat transfer gas, as described above, for example, an inert gas such as argon (Ar), helium (He), or nitrogen (N₂) can be used.

In the embodiment, the heat transfer gas supply system 110 which supplies the heat transfer gas to the heat transference varying unit 6 and the heat transfer gas supply system 120 which supplies the heat transfer gas to the gas sealing unit 8 are formed as independent systems. The pressures of the heat transfer gas supply system 110 and the heat transfer gas supply system 120 can be independently controlled. For example, Ar is sealed in the heat transference varying unit 6, and He is sealed in the gas sealing unit 8, namely, different heat transfer gases may be used in the heat transfer gas supply systems or the same heat transfer gas may be used.

With the configuration, heat input energy for the substrate 10 is transferred to the holder main body 1A through the gas sealing unit 8, the electrostatic chuck 3, and the heat transference varying unit 6. In the holder main body 1A, the heat input energy is transferred to the circulation medium 101, and waste heat is emitted through the circulation chiller 2.

More specifically, in a sputtering apparatus or an etching apparatus using the substrate 10 having a diameter of 300 mm, a heat input to the substrate 10 in a process processing state is about 1000 W. When this amount of heat input is set, the electrostatic chuck 3 the temperature of which is controlled to 450° C. seals the substrate rear-surface gas (Ar or He) 102 at a pressure of about 100 to 1 kPa by using an electrostatic chuck function. A heat transfer coefficient between the substrate 10 and the electrostatic chuck 3 at this time is controlled to 100 to 500 W/m²·K. Between the electrostatic chuck 3 and the holder main body 1A, a pressure of the sealed gas (He or Ar) 103 is controlled by the heat transference varying unit 6, the heat transfer coefficient is made variable within the range of 10 to 8000 W/m²·K, and the heat is transferred to the holder main body 1A. In the holder main body 1A, waste heat is emitted by the cooling medium 101.

More specifically, in a state in which a heat input is transitionally applied by a plasma or the like by employing a heat transfer structure obtained by gas sealing, the heat transfer coefficient is controlled to 10 to 8000 W/m²·K by adjusting a sealing pressure. In this manner, a variation in set temperature ranging from 200 to 500° C. can be controlled to within the set temperature ±10° C. within 10 seconds. Even in a situation in which a heat input is stationarily generated, when the heat transfer coefficient is controlled within the above range, the variation in set temperature can be controlled to within the set temperature ±10° C.

When the heat transference varying unit 6 is arranged, heat is also efficiently transferred to the holder main body 1A while the temperature of the substrate 10 is efficiently increased by the heater 4 of the electrostatic chuck 3. Since the heat transference varying unit 6 makes the heat transference by gas sealing variable, control can be performed such that the circulation medium 101 can be used at about 200° C. or less. Therefore, as the circulation medium 101, a medium which is conventionally used and is free from combustibility, for example, a fluorine medium such as Fluorinert or Galden can be used.

In this manner, by the pressure control of the sealed gas by the heat transference varying unit 6, the heat transfer coefficient can be made variable. Therefore, without performing a change of members between the electrostatic chuck 3 and the holder main body 1A or mechanical adjustment, the temperature of the circulation medium 101 can be set to about 200° C. or less, and temperature control can be performed such that the temperature of the electrostatic chuck 3 falls within the range of 200 to 500° C.

According to the substrate holder of the first embodiment, as shown in FIG. 2, in temperature setting within the range of 200 to 500° C., control of a substrate temperature can be realized at a high speed (within 10 seconds) and a high accuracy (within ±10° C.) by only control of a heat transfer coefficient by pressure adjustment of the sealed gas by the heat transference varying unit 6. At this time, as the waste heat emitting function with respect to a heat input by a plasma or the like, the oil-free, non-combustible circulation medium 101 can be used. The members of the electrostatic chuck 3 to the holder main body 1A need not be changed, and mechanical adjustment and the like need not be performed.

Even though thermal deformation such as warpage caused by a difference in thermal characteristics of the materials of the electrostatic chuck 3 and the holder main body 1A occurs, the gap between the electrostatic chuck 3 and the holder main body 1A serving as the heat transference varying unit 6 can absorb the deformation and secure a stable heat transfer coefficient by gas transfer.

In the embodiment, since the periphery of the heat transference varying unit 6 is sealed by only the heat-insulating member 7, even though the electrostatic chucks 3 are exchanged depending on operating temperature conditions or exchanged for maintenance, an operation can be performed more easily than a case where a heat transfer material such as indium is used.

### Second Embodiment

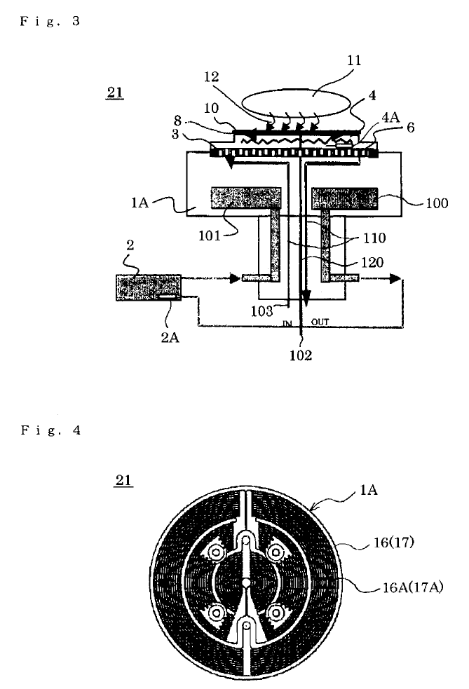

FIG. 3 is a schematic diagram showing a substrate holder according to a second embodiment. FIG. 4 is a sectional view showing a transverse sectional structure of a heat transference varying unit in the second embodiment. In the second embodiment, the same members as those in the first embodiment will be given the same reference numerals as in the first embodiment.

A substrate holder 21 according to the second embodiment is obtained by changing the structure of the heat transference varying unit 6 partitioned and formed in the gap between the holder main body 1A and the electrostatic chuck 3 in a substrate holder having the same specification as that of the first embodiment.

More specifically, the heat transference varying unit 6 according to the second embodiment is partitioned and formed such that a first plate-like member 16 and a second plate-like member 17 which have circular-arc fins 16A and 17A standing upright on counter surfaces, respectively, are arranged to face each other. The fin 16A of the first plate-like member 16 and the fin 17A of the second plate-like member 17 are arranged adjacent to each other such that the fins 16A and 17A face each other, and a vertical sectional shape of a space is corrugated.

The second embodiment basically exhibits the same effects as those in the first embodiment. In particular, according to the second embodiment, as the internal structure of the heat transference varying unit 6, a corrugated space structure is formed by the fins 16A and 17A. Therefore, a heat transfer area can be increased, and a heat transfer rate between the holder main body and the sealed gas can be increased. A characteristic effect of more increasing controllability of heat transfer by adjustment of a sealing pressure is obtained.

### Third Embodiment

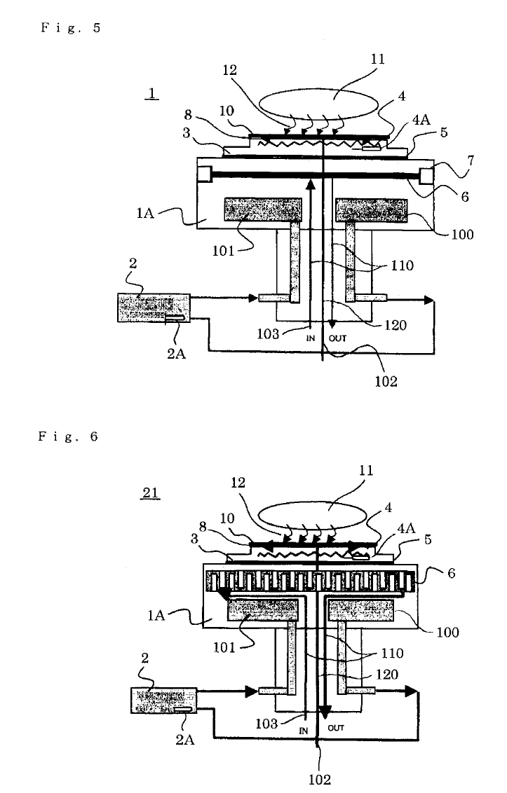

FIG. 5 is a schematic diagram showing a third embodiment of the semiconductor holder according to the present invention. FIG. 2 is a diagram for explaining a change in temperature of the substrate holder according to the present invention in relation to a conventional change in temperature.

As shown in FIG. 5, the substrate holder 1 according to the third embodiment is arranged in a vacuum vessel (not shown) of a plasma processing apparatus typified by a sputtering apparatus. The substrate holder 1 holds the substrate 10 on the electrostatic chuck 3 arranged on a substrate holding side (upper portion) of the holder main body 1A by electrostatic adsorption.

The holder main body 1A is, for example, a disk-like or columnar support member which supports a semiconductor wafer serving as the substrate 10. The circulation medium distribution path 100 to cause the circulation medium (cooling medium) 101 to flow is partitioned and formed inside the holder main body 1A. The circulation medium supplying unit 2 to circulate and supply the circulation medium 101 is connected to the circulation medium distribution path 100. The circulation medium 101 is circulated into the circulation medium distribution path 100 to give a heat exchange function and a waste heat emitting function to the holder main body 1A. In the embodiment, a circulation chiller with the temperature control sensor 2A is employed as the circulation medium supplying unit 2, and the circulation chiller 2 can be controlled to a temperature of about 200° C. or less (more specifically, temperature of 100 to 250° C.). As the circulation medium 101, for example, a fluorine medium, cooling water mixed with ethylene-glycol, or pure water can be used.

The heat transference varying unit 6 is partitioned and formed as a sealing space for the heat transfer gas (sealed gas) 103 above the circulation medium distribution path 100 inside the holder main body 1A, and the heat transference varying unit 6 is connected to the heat transfer gas supply system 110 the sealing pressure of which can be adjusted. The periphery of the heat transference varying unit 6 is partitioned by the ring-like heat-insulating member 7. As the heat-insulating member 7, for example, a material such as alumina or stainless steel having a heat transfer coefficient of 25 W/m²·K or less is given. However, the heat-insulating member 7 is more preferably formed of a material such as zirconia or quartz having a heat transfer coefficient of less than 10 W/m²·K. The heat-insulating member 7 thermally insulates an upper part of the holder main body 1A from the lower part of the holder main body 1A to make it possible to control a heat transfer coefficient by adjusting a gas sealing pressure.

The heat transference varying unit 6 sets a gap size at which 1 or more of a Knudsen number (Ku=λ/L where λ (m): a mean free path of molecules and L (m): typical length) is obtained on the basis of a mean free path of a gas to be used such that the heat transfer coefficient is made variable by adjusting the sealing pressure of the heat transfer gas. The Knudsen number is set to a value which is sufficiently larger than 1 because inter-molecule collision at this time can be neglected and a fluid can be handled as a continuum.

As the heat transfer gas, for example, an inert gas such as argon (Ar), helium (He), or nitrogen (N₂) can be used. When Ar and He are used at a substrate set temperature of 450° C., a gap (interval) of the heat transference varying unit 6 is set to 0.15 to 0.5 mm in width, and the sealing pressure is set to 100 Pa and 1000 Pa. At this time, a heat transfer coefficient becomes variable as described in the following Table 2. As in a case where there is no heat input 12 by plasma 11 or the like, when a waste heat emitting energy from the circulation medium 101 of the holder main body 1A is desired to be reduced, the sealing pressure is set to 0 Pa to minimize the heat transfer coefficient.

TABLE 2

| | | | | |
|---|---|---|---|---|
| Ar gas | 100 | Pa | 1000 | Pa |
| Gas sealed Gap 0.15 mm | 10 | W/m² · K | 100 | W/m² · K |
| He gas | 100 | Pa | 1000 | Pa |
| Gas sealed Gap 0.5 mm | 240 | W/m² · K | 2400 | W/m² · K |

The electrostatic chuck 3 incorporates therein an electrostatic adsorption electrode and holds the substrate 10 by electrostatic adsorption. In the electrostatic chuck 3, the heating unit 4 to heat the substrate 10 is incorporated. In the embodiment, as the heating unit 4, for example, a heater with the temperature control sensor 4A the temperature of which can be raised to, for example, 200 to 500° C. is employed.

A sheet heat transfer member 5 is interposed between the holder main body 1A and the electrostatic chuck 3. The sheet heat transfer member 5 is formed of a material having a heat transfer coefficient falling within the range of 10 to 200 W/m²·K, for example, a carbon sheet, an aluminum nitride sheet, or the like.

The gas sealing unit 8 for the heat transfer gas (substrate rear-surface gas) 102 is also formed in the gap between the electrostatic chuck 3 and the substrate 10, and the gas sealing unit 8 is connected to the heat transfer gas supply system 120. The gas sealing unit 8 seals the rear surface of the substrate 10 with a gas and transfers heat between the substrate 10 and the electrostatic chuck 3. As the heat transfer gas, as in the above case, for example, an inert gas such as argon (Ar), helium (He), or nitrogen (N₂) can be used.

In the embodiment, the heat transfer gas supply system 110 which supplies the heat transfer gas to the heat transference varying unit 6 and the heat transfer gas supply system 120 which supplies the heat transfer gas to the gas sealing unit 8 are formed as independent systems. The pressures of the heat transfer gas supply system 110 and the heat transfer gas supply system 120 can be independently controlled. For example, Ar is sealed in the heat transference varying unit 6, and He is sealed in the gas sealing unit 8, namely, different heat transfer gases may be used in the heat transfer gas supply systems or the same heat transfer gas may be used.

With the configuration, heat input energy for the substrate 10 is transferred to the holder main body 1A through the gas sealing unit 8, the electrostatic chuck 3, and the heat transfer member 5. In the holder main body 1A, the sealing pressures of the heat transfer gases are controlled by the heat transference varying unit 6, the heat input energy is transferred to the circulation medium 101 in the circulation medium distribution path 100 distributed under the holder main body 1A, and waste heat is emitted through the circulation chiller 2.

More specifically, in a sputtering apparatus or an etching apparatus using the substrate 10 having a diameter of 300 mm, a heat input to the substrate 10 in a process processing state is about 1000 W. When this amount of heat input is set, the electrostatic chuck 3 the temperature of which is controlled to 450° C. seals the substrate rear-surface gas (Ar or He) 102 at a pressure of about 100 to 1 kPa by using an electrostatic chuck function. A heat transfer coefficient between the substrate 10 and the electrostatic chuck 3 at this time is controlled to 100 to 500 W/m²·K. Between the electrostatic chuck 3 and the holder main body 1A, heat is transferred using an aluminum nitride sheet, a carbon sheet or the like as the heat transfer member 5 having a heat transfer coefficient of 10 to 200 w/m²·K. In the holder main body 1A, a pressure of the sealed gas (He or Ar) 103 is controlled by the heat transference varying unit 6, the heat transfer coefficient is made variable within the range of 10 to 8000 W/m²·K, and the heat is transferred to the circulation medium 101 distributed to the holder main body 1A to emit waste heat.

More specifically, in a state in which a heat input is transitionally applied by a plasma or the like by employing a heat transfer structure obtained by gas sealing, the heat transfer coefficient is controlled to 10 to 8000 W/m²·K by adjusting a sealing pressure. In this manner, a variation in set temperature ranging from 200 to 500° C. can be controlled to within the set temperature ±10° C. within 10 seconds. Even in a situation in which a heat input is stationarily generated, when the heat transfer coefficient is controlled within the above range, the variation in set temperature can be controlled to within the set temperature ±10° C.

When the heat transference varying unit 6 is arranged, heat is also efficiently transferred to the circulation medium 101 distributed under the holder main body 1A while the temperature of the substrate 10 is efficiently increased by the heater 4 of the electrostatic chuck 3. Since the heat transference varying unit 6 makes the heat transference by gas sealing variable, control can be performed such that the circulation medium 101 can be used at about 200° C. or less. Therefore, as the circulation medium 101, a medium which is conventionally used and is free from combustibility, for example, a fluorine medium such as Fluorinert or Galden can be used.

In this manner, by the pressure control of the sealed gas by the heat transference varying unit 6, the heat transfer coefficient can be made variable. Therefore, without performing a change of members between the electrostatic chuck 3 and the holder main body 1A or mechanical adjustment, the temperature of the circulation medium 101 can be set to about 200° C. or less, and temperature control can be performed such that the temperature of the electrostatic chuck 3 falls within the range of 200 to 500° C.

According to the substrate holder 1 of the third embodiment, as shown in FIG. 2, in temperature setting within the range of 200 to 500° C., control of a substrate temperature can be realized at a high speed (within 10 seconds) and a high accuracy (within ±10° C.) by only control of a heat transfer coefficient by pressure adjustment of the sealed gas by the heat transference varying unit 6. At this time, as the waste heat emitting function with respect to a heat input by a plasma or the like, the oil-free, non-combustible circulation medium 101 can be used. The members of the electrostatic chuck 3 to the holder main body 1A need not be changed, and mechanical adjustment and the like need not be performed.

Even though thermal deformation such as warpage caused by a difference in thermal characteristics of the materials of the electrostatic chuck 3 and the holder main body 1A, the gap between the electrostatic chuck 3 and the holder main body 1A serving as the heat transference varying unit 6 can absorb the deformation and secure a stable heat transfer coefficient by gas transfer.

In the embodiment, since the periphery of the heat transference varying unit 6 is sealed by only the heat-insulating member 7, even though the electrostatic chucks 3 are exchanged depending on operating temperature conditions or exchanged for maintenance, an operation can be performed more easily than a case where a heat transfer material such as indium is used.

### Fourth Embodiment

FIG. 6 is a schematic diagram showing a substrate holder according to a fourth embodiment. FIG. 4 is a sectional view showing a transverse sectional structure of a heat transference varying unit. In the fourth embodiment, the same members as those in the third embodiment will be given the same reference numerals as in the third embodiment.

A substrate holder 21 according to the fourth embodiment is obtained by changing the structure of the heat transference varying unit 6 partitioned and formed above the circulation medium distribution path 100 inside the holder main body 1A in a substrate holder having the same specification as that of the third embodiment.

More specifically, the heat transference varying unit 6 according to the fourth embodiment is partitioned and formed such that the first plate-like member 16 and the second plate-like member 17 which have the circular-arc fins 16A and 17A standing upright on counter surfaces, respectively, are arranged to face each other. The fin 16A of the first plate-like member 16 and the fin 17A of the second plate-like member 17 are arranged adjacent to each other such that the fins 16A and 17A face each other, and a vertical sectional shape of a space is corrugated.

The fourth embodiment basically exhibits the same effects as those in the third embodiment. In particular, according to the fourth embodiment, as the internal structure of the heat transference varying unit 6, a corrugated space structure is formed by the fins 16A and 17A. Therefore, a heat transfer area can be increased, and a heat transfer rate between the holder main body and the sealed gas can be increased. A characteristic effect of more increasing controllability of heat transfer by adjustment of a sealing pressure is obtained.

### Fifth Embodiment

A method of controlling a substrate temperature will be described below by using a substrate holder according to the present invention.

(1) Control Method 1

<Before Process Starts>

The substrate 10 is heated by the heating unit 4 in the electrostatic chuck 3 to increase the temperature to a set temperature and to hold the temperature constant until the process is started. At this time, the sealed gas 103 of the heat transference varying unit 6 is not supplied.

<After Process Starts>

When the substrate temperature (=electrostatic chuck temperature) is increased by a heat input from a plasma, the sealed gas 103 of the heat transference varying unit 6 is supplied, and the substrate temperature is decreased to the set temperature while maintaining a pressure of the sealed gas constant. When the substrate temperature is close to the set temperature, the pressure of the sealed gas may be decreased. After the substrate temperature reaches the set temperature, a balance between heating by the heating unit 4 and waste-heat emission through the heat transference varying unit 6 is adjusted to hold the substrate temperature at the set temperature.

(2) Control Method 2

<Before Process Starts>

The substrate 10 is heated by the heating unit 4 in the electrostatic chuck 3 to increase the temperature to a set temperature. Thereafter, the sealed gas 103 of the heat transference varying unit 6 is supplied to hold a pressure of the sealed gas at a pressure which is measured in advance and at which a heat transfer coefficient required for waste heat emission is obtained, and a heating capability of the heating unit is adjusted to hold the substrate temperature at the set temperature until the process is started.

<After Process Starts>

When the substrate temperature (=electrostatic chuck temperature) is increased by a heat input from a plasma, a balance between heating by the heating unit 4 and waste-heat emission through the heat transference varying unit 6 is adjusted to hold the substrate temperature at the set temperature.

(3) Control Method 3

<Before Process Starts>

The same operations as those in Control Method 2 are performed.

<Before Process Starts>

When the substrate temperature (=electrostatic chuck temperature) is increased by a heat input from a plasma, the pressure of the sealed gas 103 of the heat transference varying unit 6 is increased to decrease the substrate temperature. When the substrate temperature is close to the set temperature, the pressure of the sealed gas is returned to the pressure obtained before the process start. After the substrate temperature reaches the set temperature, a balance between heating by the heating unit 4 and waste-heat emission through the heat transference varying unit 6 is adjusted to hold the substrate temperature at the set temperature.

The present invention is not limited to the first to fifth embodiments, and various changes of the present invention can be effected without departing from the spirit and scope of the invention. For example, when an amount of heat transfer energy in the heat transference varying unit 6 is insufficient, the upper and lower surfaces of the heat transference varying unit 6 may be blackened to increase thermal emissivity and heat absorptivity to increase an amount of transfer energy by heat radiation.

In the heat transference varying unit 6, in order to increase gas airtightness, seal members, for example, carbon sheets which can be used under a temperature condition of 200 to 500° C. may be arranged above and below the heat-insulating member 7.

The substrate holder according to the present invention can be applied as substrate holders not only in a sputtering apparatus or a dry-etching apparatus but also in processing apparatuses such as a plasma asher apparatus, a CVD apparatus, and a liquid crystal display manufacturing apparatus having vacuum vessels.

1. A substrate holder which has an electrostatic chuck on a substrate holding side of a holder main body and electrostatically adsorbs a substrate, comprising:
a heating unit which is built in the electrostatic chuck and heats the substrate;
a circulation medium distribution path which is formed inside the holder main body and connected to a circulation medium supplying unit which circulates and supplies a circulation medium;
a heat transference varying unit which is formed by sealing a heat transfer gas in a gap between the holder main body and the electrostatic chuck and connected to a heat transfer gas supply system which can control a sealing pressure; and
a gas sealing unit which is formed by sealing a heat transfer gas in a gap between the electrostatic chuck and the substrate and connected to the heating transfer gas supply system.

2. The substrate holder according to claim 1, wherein the gap between the holder main body and the electrostatic chuck serving as the heat transference varying unit is set to 0.15 to 0.5 mm in width.

3. The substrate holder according to claim 1, wherein the heat transference varying unit makes a heat transfer coefficient variable by a sealing pressure of the heat transfer gas and the presence/absence of a gas.

4. The substrate holder according to claim 1, wherein a heat transfer gas supply system which supplies the heat transfer gas to the heat transference varying unit and the heat transfer gas supply system which supplies the heat transfer gas to the gas sealing unit are formed as independent systems, and sealing pressures of the heat transfer gas supply systems can be independently controlled.

5. The substrate holder according to claim 1, wherein a heat-insulating member is arranged around the gap between the holder main body and the electrostatic chuck serving as the heat transference varying unit.

6. The substrate holder according to claim 5, wherein the heat-insulating member is formed of a material having a heat transfer coefficient of not more than 25 W/m2·K.

7. A substrate holder which has an electrostatic chuck on a substrate holding side of a holder main body and electrostatically adsorbs a substrate, comprising:
a heating unit which is built in the electrostatic chuck and heats the substrate;
a circulation medium distribution path which is formed inside the holder main body and connected to a circulation medium supplying unit which circulates and supplies a circulation medium; and
a heat transference varying unit which is partitioned and formed as a sealing space for a heat transfer gas above the circulation medium distribution path inside the holder main body and connected to a heat transfer gas supply system which can control a sealing pressure.

8. The substrate holder according to claim 7, wherein a heat transfer member is interposed between the holder main body and the electrostatic chuck.

9. The substrate holder according to claim 8, wherein the heat transfer member is formed of a material having a heat transfer coefficient falling within the range of 10 to 200 W/m2·K.

10. The substrate holder according to claim 9, wherein the heat transfer member is a carbon sheet or an aluminum nitride sheet.

11. The substrate holder according to claim 7, wherein a heat transfer gas is sealed between the substrate and the electrostatic chuck.

12. The substrate holder according to claim 11, wherein a heat transfer gas supply system which supplies the heat transfer gas to the heat transference varying unit and the heat transfer gas supply system which supplies the heat transfer gas to between the substrate and the electrostatic chuck are formed as independent systems, and sealing pressures of the heat transfer gas supply systems can be independently controlled.

13. The substrate holder according to claim 7, wherein a periphery of the heat transference varying unit is partitioned by a heat-insulating member.

14. The substrate holder according to claim 13, wherein the heat-insulating member is formed of a material having a heat transfer coefficient of not more than 25 W/m2·K.

15. The substrate holder according to claim 1, wherein the heating unit is a heater which can control a temperature.

16. The substrate holder according to claim 1, wherein the circulation medium is a fluorine medium, cooling water mixed with ethylene-glycol, or pure water.

17. The substrate holder according to claim 1, wherein the heat transference varying unit is partitioned and formed such that a first plate-like member and a second plate-like member which have fins standing upright on counter surfaces are arranged to face each other, and the fin of the first plate-like member and the fin of the second plate-like member are arranged adjacent to each other such that the fins face each other.

18. The substrate holder according to claim 1, wherein the heat transfer gas is helium, argon, or nitrogen.
